(19) United States
(12) Patent Application Publication
(10) Pub. No.: US 2014/0290733 A1
(43) Pub. Date: Oct. 2, 2014

(54) PHOTOELECTRIC CONVERSION ELEMENT AND PHOTOVOLTAIC CELL

(71) Applicant: SEIKO EPSON CORPORATION, Tokyo (JP)

(72) Inventors: Yasuaki HAMADA, Chino-shi (JP); Satoshi KIMURA, Nagano-ken (JP); Setsuya IWASHITA, Nirasaki-shi (JP); Satoru HOSONO, Azumino-shi (JP)

(73) Assignee: SEIKO EPSON CORPORATION, Tokyo (JP)

(21) Appl. No.: 14/221,899

(22) Filed: Mar. 21, 2014

(30) Foreign Application Priority Data
Mar. 28, 2013 (JP) 2013-067944

(51) Int. Cl. H01L 31/0224

(52) U.S. Cl. CPC H01L 31/0224
USPC 136/256

(57) ABSTRACT

A photoelectric conversion element includes a ferroelectric layer as a photoelectric conversion layer. The ferroelectric layer is formed from a polycrystalline ferroelectric material and includes a plurality of domains. Adjacent two of the plurality of domains have different polarized states.

### BACKGROUND

1. Technical Field

The present invention relates to a photoelectric conversion element using an oxide semiconductor, and a photovoltaic cell.

2. Related Art

According to the related art, a photovoltaic cell (photoelectric conversion element) using silicon has gathered attention as an environmentally friendly power source. The photovoltaic cell using silicon is formed by a PN junction on a single crystal or polycrystalline silicon substrate (refer to JP-A-1-220380).

However, such a photovoltaic cell has high manufacturing costs, and further a high degree of control over the manufacturing conditions is necessary. Furthermore, a large amount of energy is necessary in manufacturing, and it cannot be said that the power source necessarily saves energy.

Dye-sensitized photovoltaic cells which have low manufacturing costs, and further, use little manufacturing energy are being developed as next generation photovoltaic cells that replace the current photovoltaic cells. However, because an electrolyte with high vapor pressure is used in the dye-sensitized photovoltaic cell, there is a problem with the electrolyte volatilizing.

Furthermore, as a photovoltaic cell of a recent and newly developed method, there is a method in which a domain structure of a ferroelectric material is used (for example, refer to S. Y. Yang, J. Seidel, S. J. Byrnes, P. Shafer, C.-H. Yang, M. D. Rossell, P. Yu, Y.-H. Chu, J. F. Scott, J. W. Ager, III, L. W. Martin, and R. Ramesh: Nature Nanotechnology 5 (2010) p. 143).

However, S. Y. Yang, J. Seidel, S. J. Byrnes, P. Shafer, C.-H. Yang, M. D. Rossell, P. Yu, Y.-H. Chu, J. F. Scott, J. W. Ager, III, L. W. Martin, and R. Ramesh: Nature Nanotechnology 5 (2010) p. 143 reports that when a single crystal ferroelectric has a domain structure, electricity is generated through light irradiation, and the prospects for practical usage are a completely unknown quantity.

### SUMMARY

An advantage of some aspects of the invention is to provide a novel photoelectric conversion element and a photovoltaic cell.

According to an aspect of the invention, there is provided a photoelectric conversion element includes a ferroelectric layer as a photoelectric conversion layer. The ferroelectric layer is formed from a polycrystalline ferroelectric material and includes a plurality of domains. Adjacent two of the plurality of domains have different polarized states.

According to the aspect, since the ferroelectric layer formed from a polycrystal has a domain structure in which domains having different polarized states are alternately arranged, electric power due to light irradiation can be extracted.

Here, it is preferable that lead-out electrodes that extract electric power be provided on the ferroelectric layer. In so doing, electric power generated by light irradiation can be extracted through the lead-out electrodes.

It is preferable that the ferroelectric layer is formed by a polarization treatment. In so doing, the domain structure can be reliably formed on a ferroelectric layer formed from a polycrystal.

It is preferable that two or more polarized electrodes be included for setting the ferroelectric layer to two different polarized states. In so doing, the domain structure can be reliably formed on a ferroelectric layer formed from a polycrystal through the two or more polarized electrodes.

It is preferable that all of the polarized electrodes be provided on one surface of the ferroelectric layer. In so doing, the polarized electrodes are easily formed, and a domain structure can be reliably formed on a ferroelectric layer formed from a polycrystal.

It is preferable that all of the electrodes arranged on one surface of the ferroelectric layer be formed of a material having a larger band gap than the ferroelectric material that forms the ferroelectric layer. In so doing, light can be efficiently incorporated into the ferroelectric layer.

It is preferable that the ferroelectric layer be formed on a base. In so doing, a ferroelectric layer can be simply and efficiently formed.

It is preferable that either the base and all of the electrodes arranged between the ferroelectric layer and the base, or all of the electrodes arranged on a surface of the ferroelectric layer not contacting the base be formed from a material having a larger band gap than the ferroelectric material that forms the ferroelectric layer. In so doing, light can be efficiently incorporated into the ferroelectric layer.

It is preferable that the base be a perovskite oxide. In so doing, a ferroelectric layer with a single orientation may be obtained, and a high quality domain structure can be reliably formed.

It is preferable that the base have conductivity or a conductive oxide layer be formed between the base and the ferroelectric layer. In so doing, a ferroelectric layer can be simply and efficiently formed.

According to another aspect of the invention, there is provided a photovoltaic cell using the photoelectric conversion element.

According to the aspect, since a photoelectric conversion element that performs photoelectric conversion due to the domain structure is included, a highly reproducible and low cost photovoltaic cell can be comparatively simply realized.

### BRIEF DESCRIPTION OF THE DRAWINGS

The invention will be described with reference to the accompanying drawings, wherein like numbers reference like elements.

FIG. 1 is a cross-sectional view showing a schematic configuration of a photoelectric conversion element according to Embodiment 1 of the invention.

FIG. 2 is a cross-sectional view of a state in which polarized electrodes that perform the polarization treatment in FIG. 1 are arranged.

FIG. 3 is a cross-sectional view showing a schematic configuration of a photoelectric conversion element according to Embodiment 2 of the invention.

FIG. 4 is a cross-sectional view of a state in which polarized electrodes that perform the polarization treatment in FIG. 3 are arranged.

FIG. 5 is a cross-sectional view showing a schematic configuration of a photoelectric conversion element according to Embodiment 3 of the invention.

FIG. 6 is a cross-sectional view of a state in which polarized electrodes that perform the polarization treatment in FIG. 5 are arranged.

FIG. 7 is a cross-sectional view showing a schematic configuration of a photoelectric conversion element according to Embodiment 4 of the invention.

FIG. 8 is a cross-sectional view of a state in which polarized electrodes that perform the polarization treatment in FIG. 7 are arranged.

FIG. 9 is a diagram showing the results of the polarization treatment in Example 1.

FIG. 10 is a diagram showing the X-ray diffraction peak value in Example 2.

FIG. 11 is a diagram showing the results of the polarization treatment in Example 2.

### DESCRIPTION OF EXEMPLARY EMBODIMENTS

Below, embodiments of the present invention are described in detail based on drawings. The embodiments show one form of the invention, and arbitrary modifications are possible within the scope of the invention without limiting the invention to the embodiments.

### Embodiment 1

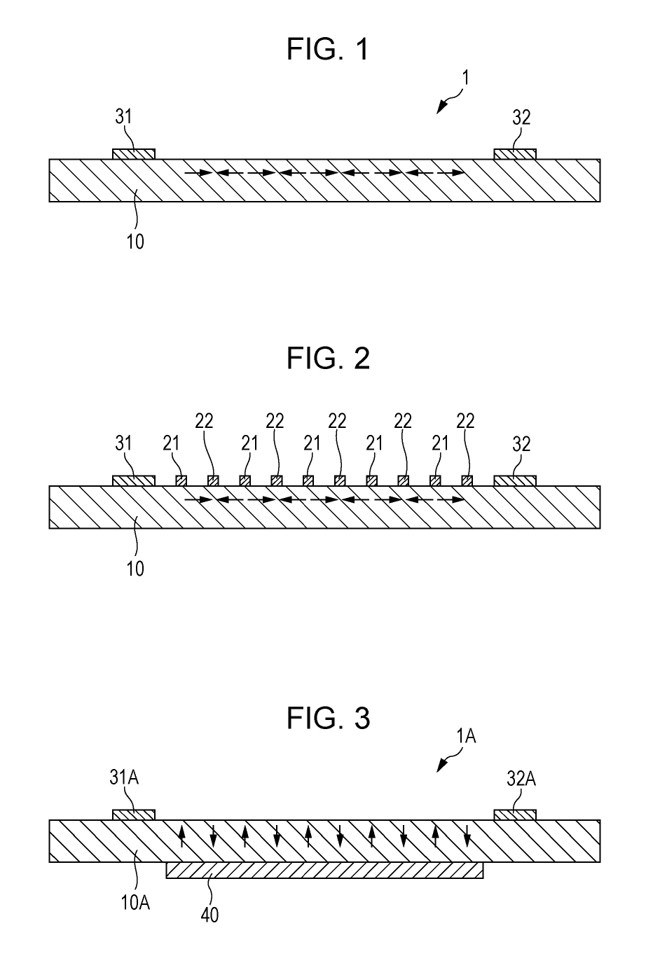

FIG. 1 is a cross-sectional view showing a schematic configuration of a photoelectric conversion element (photovoltaic cell) according to Embodiment 1 of the invention.

As shown in FIG. 1, the photoelectric conversion element 1 includes a domain structure in which domains including different polarized states in the surface layer portion are alternately arranged, as shown by the arrow, and include a ferroelectric layer 10 that functions as a photoelectric conversion layer. The polarization is formed on the surface layer portion of the ferroelectric layer 10, and the polarization direction becomes parallel to the surface. Then, a wall portion is formed between domains that becomes a boundary of the different polarizations. One pair of lead-out electrodes 31 and 32 is provided on either side in the parallel direction in which the domains in which the polarization direction of the ferroelectric layer 10 is different are alternately arranged.

Here, examples of the ferroelectric layer 10 include, for example, lead titanate (PbTiO₃), lead zirconate titanate (Pb(Zr,Ti)O₃), barium titanate (BaTiO₃), lithium niobate (LiNbO₃), lithium tantalate (LiTaO₃), sodium niobate (NaNbO₃), sodium tantalate (NaTaO₃), potassium niobate (KNbO₃), potassium tantalate (KTaO₃), bismuth sodium titantate ((Bi_{1/2}Na_{1/2})TiO₃), bismuth potassium tantalate ((Bi_{1/2}K_{1/2})TiO₃), bismuth ferrate (BiFeO₃), strontium bismuth tantalate (SrBi₂Ta₂O₉), strontium bismuth niobate (SrBi₂Nb₂O₉), or bismuth titanate (Bi₄Ti₃O₁₂) and solid solutions having at least one thereof as a component; however, there is no limitation on the material if the material is ferroelectric. Examples of the method of forming the ferroelectric layer 10 include a method of sintering by forming a raw material powder or a raw material solution in a desired shape, and a method of growing and cutting away a polycrystalline substrate; however, there is no limitation to the above methods if a massive ferroelectric layer 10 is obtained. In addition, the thickness of the ferroelectric layer 10 may be extremely thin because only the vicinity of the surface is polarized as described later; however, it is not problematic if the thickness is of any extent in order that mechanical strength as a structure be maintained. It is preferable that the flatness of the surface of the ferroelectric layer 10 on which the electrodes are arranged be as flat as possible; however, it is not problematic for there to be some surface roughness if in a range in which the electrodes have conductivity. It is preferable that a ferroelectric layer be used that is aligned in a predetermined direction, for example, aligned to the (100) surface.

Examples of the material of the lead-out electrodes 31 and 32 include metal elements, such as platinum (Pt), iridium (Ir), gold (Au), aluminum (Al), copper (Cu), titanium (Ti), and stainless steel; tin oxide-based conductive materials, such as indium tin oxide (ITO), and fluorine-doped tin oxide (FTO); zinc oxide-based conductive materials, conductive oxides, such as strontium ruthenate (SrRuO₃), lanthanum nickelate (LaNiO₃), element doped strontium titanate; and conductive polymers; however, there is not particular limitation thereto, if the material has conductivity. Examples of the method of forming the first electrode 21 and the second electrode 22, as well as the lead-out electrodes 31 and 32 include, gas phase methods, such as a CVD method, liquid phase methods, such as a coating method, solid phase methods, such as a sputtering method, and printing methods; however, the method is not limited thereto. The thickness of the lead-out electrodes 31 and 32 is not limited, if within a range able to exhibit conductivity. Although the lead-out electrodes 31 and 32 are preferably formed from the same material, it goes without saying that the materials may also be different.

The domain structure of the ferroelectric layer 10 of the photoelectric conversion element 1 according to the present embodiment of the invention is formed by a polarization treatment. FIG. 2 shows a cross-sectional view of a state in which polarized electrodes that perform the polarization treatment of the ferroelectric layer 10 are arranged.

The first electrode 21 and the second electrode 22 that are polarized electrodes are alternately arranged in parallel along one direction (the left to right direction in the drawing), and extend in a direction orthogonal to the direction (direction orthogonal to the paper surface). A voltage may be applied by each first electrode 21 and each second electrode 22 being connected to one another, or a voltage may be applied to each first electrode 21 and each second electrode 22 with a probe. In either case, it is possible to perform a polarization treatment by applying a voltage of a coercive voltage or higher obtained from the electrode gap and a coercive electric field of the ferroelectric material between the first electrode 21 and the second electrode 22. In so doing, as shown by the arrow in FIG. 2, polarization is performed to be in alternately differing directions in the region between the first electrode 21 and the second elect rode 22. The polarization is formed on the surface layer portion of the ferroelectric layer 10, and the polarization direction becomes parallel to the surface. The polarization direction becomes the parallel direction (the above one direction) in which the first electrode 21 and the second electrode 22 are alternately aligned. A wall portion that is a boundary of different polarizations is formed on the lower side of the electrode of the first electrode 21 and the second electrode 22. The first electrode 21 and the second electrode 22 are preferably formed from the same material as the above-described lead-out electrodes 31 and 32.

By performing the polarization treatment, a domain structure is reliably formed on the ferroelectric layer 10, and, in so doing, the ferroelectric layer functions as a photoelectric conversion element.

In order to easily perform the polarization treatment, it is more preferable that the gap between the first electrode 21 and the second electrode 22 be narrow. In addition, because a portion of the function is impaired when a number of regions that are not polarized (corresponding to the wall portion) are present, it is more preferable that the width of the first electrode 21 and the second electrode 22 (electrode width) be narrow.

The photoelectric conversion element 1 subjected to polarization treatment in this way generates electric power when irradiated with light. The light for power generation is preferably irradiated from a surface of the ferroelectric layer 10 in which the first electrode 21 and the second electrode 22 are not arranged in cases in which the material of the first electrode 21 and the second electrode 22 reflects or absorbs light, particularly visible light, that is the target. In a case in which the first electrode 21 and the second electrode 22 neither reflect nor absorb light that is the target, light may be irradiated from any surface.

The electric power generated by light being irradiated is extracted through wirings by the lead-out electrodes 31 and 32, and it is possible to transmit an external load.

In addition, since, basically, only the polarization treatment is preferably performed at first, the photoelectric conversion element is preferably formed by setting the state (refer to FIG. 1) in which the first electrode 21 and the second electrode 22 are removed. Naturally, photoelectric conversion may be performed in a state in which the first electrode 21 and the second electrode 22 are included.

### Embodiment 2

FIG. 3 is a cross-sectional view showing a schematic configuration of a photoelectric conversion element according to Embodiment 2 of the invention.

As shown in FIG. 3, the photoelectric conversion element 1A has a domain structure in which domains including different polarization states are alternately arranged as indicated by the arrow. The polarization has a polarization direction parallel to the thickness direction of the ferroelectric layer 10A, and a wall portion is formed between domains that are boundaries of different polarizations. In addition, one pair of lead-out electrodes 31A and 32A is provided on either side in the parallel direction in which the domains in which the polarization direction of the ferroelectric layer 10A is different are alternately arranged.

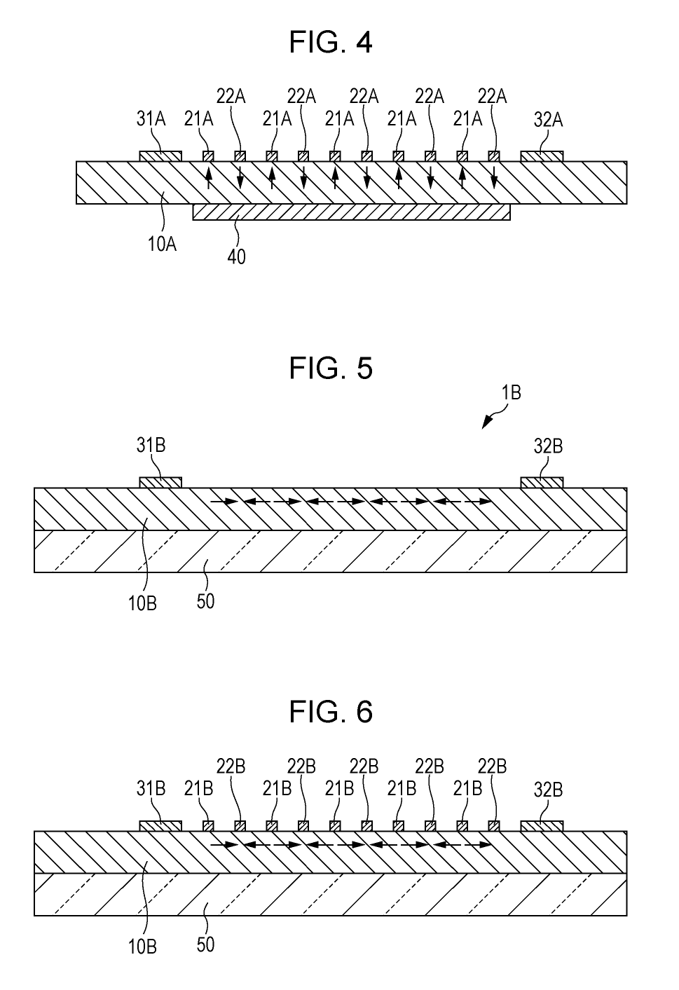

The domain structure of the ferroelectric layer 10A of the photoelectric conversion element 1 according to the present embodiment of the invention is formed by a polarization treatment. FIG. 4 shows a cross-sectional view of a state in which polarized electrodes that perform the polarization treatment of the ferroelectric layer 10A are arranged.

The first electrode 21A and the second electrode 22A that are polarized electrodes, and a common electrode 40 are provided on both sides of the ferroelectric layer 10A. Here, the first electrode 21A and the second electrode 22A are alternately arranged in parallel along one direction (the left to right direction in the drawing), and extend in a direction orthogonal to the direction (direction orthogonal to the paper surface). A voltage may be applied by each first electrode 21A and each second electrode 22A being connected to one another, or a voltage may be applied to each first electrode 21A and each second electrode 22A with a probe. In either case, it is possible to perform a polarization treatment by applying a voltage of a coercive voltage or higher obtained from the thickness of the ferroelectric layer 10A and a coercive electric field of the ferroelectric material between the first electrode 21A and the second electrode 22A, and the common electrode 40. In so doing, as shown by the arrow in FIG. 4, polarization is performed to be in alternately differing directions in the region between the first electrode 21A and the second electrode 22A, and the common electrode 40. The polarization is formed in the region between the first electrode 21A and the second electrode 22A, and the common electrode 40 of the ferroelectric layer 10A, and the polarization direction becomes parallel to the thickness direction of the ferroelectric layer 10A. In addition, a wall portion that is a polarization boundary is formed in the region between the first electrode 21A and the second electrode 22A, and the common electrode 40. The method of voltage application is not particularly limited if a method in which a domain structure as described above is formed; however, a voltage may be sequentially applied to the first electrode 21A and the second electrode 22A, or the voltage may be applied at the same time.

By performing the polarization treatment, a domain structure is reliably formed on the ferroelectric layer 10A, and, in so doing, the ferroelectric layer functions as a photoelectric conversion element.

In order to easily perform the polarization treatment, it is more preferable that the gap between the first electrode 21A and the second electrode 22A be narrow. Because a portion of the function is impaired when a number of regions that are not polarized (corresponding to the wall portion) are present, it is more preferable that the width of the first electrode 21A and the second electrode 22A (electrode width) be narrow.

According to the present embodiment of the invention, at least one of the first electrode 21A and the second electrode 22A arranged above the ferroelectric layer 10A, and the common electrode 40 arranged below the ferroelectric layer 10A is preferably formed from a material having a larger band gap than the ferroelectric material used in the ferroelectric layer 10A. For example, if the ferroelectric material is BiFeO₃ (band gap=2.6 eV), and the material of the common electrode 40 is a metal (no band gap), it is preferable that the material of the first electrode 21A and the second electrode 22A arranged above the ferroelectric layer 10 be a conductive oxide material (band gap>3.2 eV), and if the material of the first electrode 21A and the second electrode 22A arranged above the ferroelectric layer 10 is a metal (no band gap), it is preferable that the material of the common electrode 40 be a conductive oxide material (band gap>3.2 eV).

The photoelectric conversion element 1A subjected to polarization treatment in this way generates electric power when irradiated with light. The light for power generation is preferably irradiated from a surface of the ferroelectric layer 10 in which the first electrode 21 and the second electrode 22 are not arranged in cases in which the material of the first electrode 21A and the second electrode 22A reflects or absorbs light, particularly visible light, that is the target. In a case in which the first electrode 21 and the second electrode 22 neither reflect nor absorb light that is the target, light may be irradiated from any surface.

The electric power generated by light being irradiated is extracted through wirings by the lead-out electrodes 31A and 32A, and it is possible to transmit an external load.

In addition, since, basically, only the polarization treatment may be performed at first, the photoelectric conversion element may be formed by setting the state (refer to FIG. 3) in which the first electrode 21A and the second electrode 22A are removed. Naturally, photoelectric conversion may be performed in a state in which the first electrode 21A and the second electrode 22A are included.

### Embodiment 3

FIG. 5 is a cross-sectional view showing a schematic configuration of a photoelectric conversion element 1B according to the embodiment of the invention.

In the present embodiment, the ferroelectric layer 10B is formed on the base 50, and lead-out electrodes 31B and 32B are provided on the ferroelectric layer 10B.

The ferroelectric layer 10B of the photoelectric conversion element 1B is similar to Embodiment 1 on the point of having a domain structure in which domains that include different polarized states are alternately arranged in the surface layer portion. The polarization is formed on the surface layer portion of the ferroelectric layer 10B, and the polarization direction becomes parallel to the surface. Then, a wall portion is formed between domains that become a boundary of the different polarizations.

Examples of the base 50 include, for example, various glass materials, transparent ceramic materials such as quartz or sapphire, polymer materials, such as polyimides, semi-conductor materials, such as Si, and various other compounds such as SiC; however, there is no limitation to these materials if the material satisfies the conditions described later.

It is possible for the ferroelectric layer 10B to use the same materials and conditions as Embodiment 1. Here, it is possible to use thin film forming methods including gas phase methods, such as a CVD method, liquid phase methods, such as a coating method, solid phase methods, such as a sputtering method, and printing methods as the method of forming ferroelectric layer 10B, in addition to a method of adhering the above-described massive ferroelectric layer to the base 50.

The domain structure of the ferroelectric layer 10B of the photoelectric conversion element 1B according to the present embodiment is formed by a polarization treatment. FIG. 6 shows a cross-sectional view of a state in which polarized electrodes that perform the polarization treatment of the ferroelectric layer 10B are arranged.

The first electrode 21B and the second electrode 22B that are polarized electrodes are alternately arranged in parallel along one direction (the left to right direction in the drawing), and extend in a direction orthogonal to the direction (direction orthogonal to the paper surface). A voltage may be applied by each first electrode 21B and each second electrode 22B being connected to one another, or a voltage may be applied to each first electrode 21B and each second electrode 22B with a probe. In either case, it is possible to perform a polarization treatment by applying a voltage of a coercive voltage or higher obtained from the electrode gap and a coercive electric field of the ferroelectric material between the first electrode 21B and the second electrode 22B. In so doing, as shown by the arrow in FIG. 6, polarization is performed to be in alternately differing directions in the region between the first electrode 21B and the second electrode 22B. The polarization is formed on the surface layer portion of the ferroelectric layer 10B, and the polarization direction becomes parallel to the surface. The polarization direction becomes the parallel direction (the above one direction) in which the first electrode 21B and the second electrode 22B are alternately aligned. In addition, a wall portion that is a boundary of different polarizations is formed on the lower side of the electrode of the first electrode 21B and the second electrode 22B. The first electrode 21B and the second electrode 22B, and the lead-out electrodes 31B and 32B are preferably formed from the same material as the above-described lead-out electrodes 31 and 32.

By performing the polarization treatment, a domain structure is reliably formed on the ferroelectric layer 10, and, in so doing, the ferroelectric layer functions as a photoelectric conversion element.

In order to easily perform the polarization treatment, it is more preferable that the gap between the first electrode 21B and the second electrode 22B be narrow. In addition, because a portion of the function is impaired when a number of regions that are not polarized (corresponding to the wall portion) are present, it is more preferable that the width of the first electrode 21B and the second electrode 22B (electrode width) be narrow.

The photoelectric conversion element 1B subjected to polarization treatment in this way generates electric power when irradiated with light. The light for power generation is preferably irradiated from a surface of the ferroelectric layer 10B in which the first electrode 21B and the second electrode 22B are not arranged in cases in which the material of the first electrode 21B and the second electrode 22B reflects or absorbs light, particularly visible light, that is the target. In a case in which the first electrode 21B and the second electrode 22B neither reflect nor absorb light that is the target, light may be irradiated from any surface.

The electric power generated by light being irradiated is extracted through wirings by the lead-out electrodes 31B and 32B, and it is possible to transmit an external load.

In addition, since, basically, only the polarization treatment may be performed at first, the photoelectric conversion element may be formed by setting the state (refer to FIG. 1) in which the first electrode 21B and the second electrode 22B are removed. Naturally, photoelectric conversion may be performed in a state in which the first electrode 21B and the second electrode 22B are included.

In the present embodiment, since the first electrode 21B and the second electrode 22B and the base 50 are arranged on different surfaces of the ferroelectric layer 10B, it is preferable that at least one thereof be a material with a larger band gap than the ferroelectric material used in the ferroelectric layer 10B. It is possible to efficiently incorporate light into the ferroelectric layer by using such a material. For example, the ferroelectric material is BiFeO₃ (band gap=2.6 eV), and if the base 50 is Si (band gap=1.1 eV), it is preferable that the material of the first electrode 21B and the second electrode 22B be a conductive oxide material (band gap>3.2 eV), whereas if the material of the first electrode 21B and the second electrode 22B is a metal (no band gap), it is preferable that the material of the base 50 be a material such as a polymer, a glass, or quartz (band gap>7.8 eV). Among these, it is particularly preferable that the material be a perovskite oxide such as SrTiO₃. It is possible to obtain a ferroelectric layer with a single orientation, and to reliably form a high quality domain structure by using such a material.

The polarization treatment and power generation of the photoelectric conversion element 1B of the present embodiment are the same as the above-described Embodiment 1.

### Embodiment 4

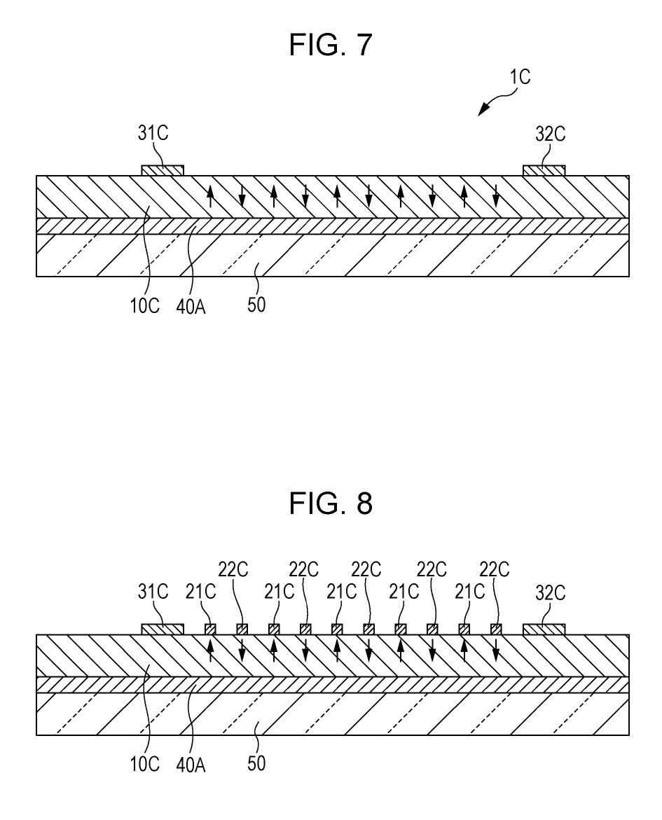

FIG. 7 is a cross-sectional view showing a schematic configuration of a photoelectric conversion element 1C according to the present embodiment.

In the present embodiment, the ferroelectric layer 10C is formed on the base 50 on which the common electrode 40A is provided on a surface thereof, and lead-out electrodes 31C and 32C are provided on the ferroelectric layer 10C.

As shown in FIG. 7, the photoelectric conversion element 1C has a domain structure in which domains including different polarization states are alternately arranged as indicated by the arrow. The polarization has a polarization direction parallel to the thickness direction of the ferroelectric layer 10C, and a wall portion is formed between domains that are boundaries of different polarizations. One pair of lead-out electrodes 31C and 32C is provided on either side in the parallel direction in which the domains in which the polarization direction of the ferroelectric layer 10C is different are alternately arranged.

The domain structure of the ferroelectric layer 10C of the photoelectric conversion element 1C according to the present embodiment is formed by a polarization treatment. FIG. 8 shows a cross-sectional view of a state in which polarized electrodes that perform the polarization treatment of the ferroelectric layer 10C are arranged.

The first electrode 21C and the second electrode 22C that are polarized electrodes, and the common electrode 40A are provided on both sides of the ferroelectric layer 10C. Here, the first electrode 21C and the second electrode 22C are alternately arranged in parallel along one direction (the left to right direction in the drawing), and extend in a direction orthogonal to the direction (direction orthogonal to the paper surface). A voltage may be applied by each first electrode 21C and each second electrode 22C being connected to one another, or a voltage may be applied to each first electrode 21C and each second electrode 22C with a probe. In either case, it is possible to perform a polarization treatment by applying a voltage of a coercive voltage or higher obtained from the thickness of the ferroelectric layer 10C and a coercive electric field of the ferroelectric material between the first electrode 21C and the second electrode 22C, and the common electrode 40A. In so doing, as shown by the arrow in FIG. 8, polarization is performed to be in alternately differing directions in the region between the first electrode 21C and the second electrode 22C, and the common electrode 40A. The polarization is formed in the region between the first electrode 21C and the second electrode 22C, and the common electrode 40A of the ferroelectric layer 10C, and the polarization direction becomes parallel to the thickness direction of the ferroelectric layer 10C. A wall portion that is a polarization boundary is formed in the region between the first electrode 21C and the second electrode 22C, and the common electrode 40A. The method of voltage application is not particularly limited if a method in which a domain structure as described above is formed; however, a voltage may be sequentially applied to the first electrode 21C and the second electrode 22C, or the voltage may be applied at the same time.

By performing the polarization treatment, a domain structure is reliably formed on the ferroelectric layer 10C, and, in so doing, the ferroelectric layer functions as a photoelectric conversion element.

In order to easily perform the polarization treatment, it is more preferable that the gap between the first electrode 21C and the second electrode 22C be narrow. In addition, because a portion of the function is impaired when a number of regions that are not polarized (corresponding to the wall portion) are present, it is more preferable that the width of the first electrode 21C and the second electrode 22C (electrode width) be narrow.

According to the present embodiment, it is preferable that at least one of the first electrode 21C and the second electrode 22C arranged above the ferroelectric layer 10C, and the common electrode 40A arranged below the ferroelectric layer 10C be formed from a material having a larger band gap than the ferroelectric material used in the ferroelectric layer 10C. For example, if the ferroelectric material is BiFeO₃ (band gap=2.6 eV), and the material of the common electrode 40A is a metal (no band gap), it is preferable that the material of the first electrode 21C and the second electrode 22C arranged above the ferroelectric layer 10C be a conductive oxide material (band gap>3.2 eV), and if the material of the first electrode 21C and the second electrode 22C arranged above the ferroelectric layer 10C is a metal (no band gap), it is preferable that the material of the common electrode 40A be a conductive oxide material (band gap>3.2 eV).

The photoelectric conversion element 1C subjected to polarization treatment in this way generates electric power when irradiated with light. It is preferable that the light for power generation be irradiated from a surface of the ferroelectric layer 10C in which the first electrode 21C and the second electrode 22C are not arranged in cases in which the material of the first electrode 21C and the second electrode 22C reflects or absorbs light, particularly visible light, that is the target. In a case in which the first electrode 21C and the second electrode 22C neither reflect nor absorb light that is the target, light may be irradiated from any surface.

The electric power generated by light being irradiated is extracted through wirings by the lead-out electrodes 31C and 32C, and it is possible to transmit an external load.

In addition, since, basically, only the polarization treatment may be performed at first, the photoelectric conversion element may be formed by setting the state (refer to FIG. 3) in which the first electrode 21C and the second electrode 22C are removed. Naturally, photoelectric conversion may be performed in a state in which the first electrode 21c and the second electrode 22C are included.

The polarization treatment and power generation of the photoelectric conversion element 1C of the present embodiment are the same as the above-described Embodiment 2.

### Example 1

A thin film of a BiFeO₃-based polycrystalline ferroelectric material was formed on a glass substrate on which a plurality of ITO electrodes is formed, and a photoelectric conversion element in which PT power lead-out electrodes are formed was prepared.

First, an electrode pattern was formed with a resist on the glass substrate, and ITO electrodes were formed by removing the resist after the ITO electrodes were formed by an RF sputtering method. The electrodes are formed by a combination of two types of 120 μm and 50 μm, and 70 μm and 100 μm as a combination of the electrode width and the electrode gap.

A thin film of a BiFeO₃-based ferroelectric material is formed by a spin coating method. A solution was synthesized by mixing 2-ethyl hexanoic acid in a ligand and various solutions of Bi, La, Fe and Mn in which n-octane is used as a solvent at a ratio of the amount of substance of 80:20:95:5. Next, the synthesized solution is coated on a glass substrate, on which an ITO electrode pattern is formed, at 2,000 rpm with a spin coating method and heated for two minutes at 350° C. after heating for two minutes at 150° C. After this process was repeated three times, heating was performed for five minutes at 650° C. using an RTA. By repeating the above process three times, a 650 nm-thick BiFeO₃-based thin film composed of a total of nine layers was prepared.

Next, the photoelectric conversion element according to Example 1 was prepared by preparing a 100 nm Pt film with a sputtering method on the BiFeO₃-based thin film.

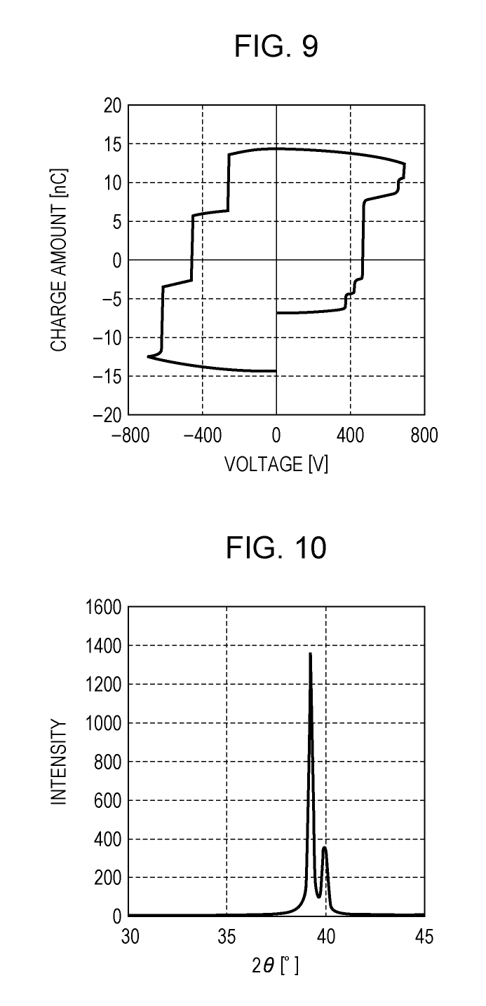

A polarization treatment was performed with respect to the prepared element with a 700 V, 25 Hz triangular wave. FIG. 9 shows the results of a polarization treatment. A hysteresis curve in which there is a step difference for an electrode pattern in which there is a plurality of electrode gaps is drawn; however, polarization treatment was confirmed.

### Example 2

A thin film of a BiFeO₃-based polycrystalline ferroelectric material was formed on a SrTiO₃ (111) substrate doped with 0.05 wt % of Nb, and a photoelectric conversion element in which a PT electrode is formed was prepared.

A thin film of a BiFeO₃-based ferroelectric material is formed by a spin coating method. A solution was synthesized by mixing 2-ethyl hexanoic acid in a ligand and various solutions of Bi, Fe, Mn, and Ba in which n-octane is used in a solvent at a ratio of the amount of substance of 75:71.25:4.75:25:25. Next, the synthesized solution was coated on a SrTiO₃ (111) substrate doped with 0.05 wt % of Nb, at 3,000 rpm with a spin coating method and heated for two minutes at 450° C. after heating for two minutes at 200° C. After this process was repeated twice, heating was performed for five minutes at 800° C. using an RTA. By repeating the above process six times, an 830 nm thick BiFeO₃-based thin film composed of a total of 12 layers was prepared.

Next, the photoelectric conversion element according to Example 2 was prepared by preparing a 100 nm Pt film on which a desired pattern is arranged with a sputtering method on the BiFeO₃-based thin film.

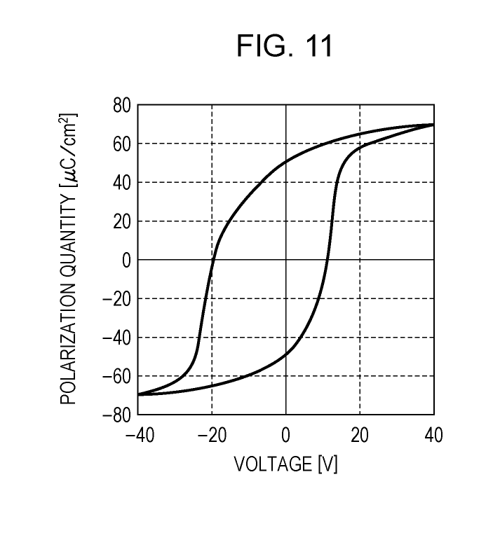

The prepared element inherits the alignment of the Nb doped SrTiO₃ (111) substrate as shown in the drawing showing the X-ray diffraction peak value of FIG. 10, it is understood that a good quality polycrystalline film is formed. Polarization treatment was performed with a 40 V, 1 kHz triangular wave, and that a polarization treatment as shown in FIG. 11 was confirmed.

The entire disclosure of Japanese Patent Application No. 2013-067944, filed Mar. 28, 2013 is incorporated by reference herein.

What is claimed is:

1. A photoelectric conversion element comprising:
a ferroelectric layer as a photoelectric conversion layer, the ferroelectric layer formed from a polycrystalline ferroelectric material and including a plurality of domains, adjacent two of the plurality of domains having different polarized states.

2. The photoelectric conversion element according to claim 1, wherein lead-out electrodes that extract electric power are provided on the ferroelectric layer.

3. The photoelectric conversion element according to claim 1, wherein the ferroelectric layer is formed by polarization treatment.

4. The photoelectric conversion element according to claim 1, further comprising two or more polarized electrodes for setting the ferroelectric layer to two different polarized states.

5. The photoelectric conversion element according to claim 4, wherein all of the polarized electrodes are arranged on one surface of the ferroelectric layer.

6. The photoelectric conversion element according to claim 4, wherein all of the electrodes arranged on one surface of the ferroelectric layer are formed from a material having a lager band gap than a ferroelectric material that forms the ferroelectric layer.

7. The photoelectric conversion element according to claim 1, wherein the ferroelectric layer is formed on a base.

8. The photoelectric conversion element according to claim 7, wherein either the base and all of the electrodes arranged between the ferroelectric layer and the base, or all of the electrodes arranged on a surface of the ferroelectric layer not contacting the base are formed from a material having a larger band gap than the ferroelectric material that forms the ferroelectric layer.

9. The photoelectric conversion element according to claim 7, wherein the base is a perovskite oxide.

10. The photoelectric conversion element according to claim 7, wherein the base has conductivity or a conductive oxide layer is formed between the base and the ferroelectric layer.

11. A photovoltaic cell comprising the photoelectric conversion element according to claim 1.
